(19) United States
(12) Patent Application Publication
(10) Pub. No.: US 2012/0108035 A1
(43) Pub. Date: May 3, 2012

(54) Method of Fabricating Semiconductor Device

(76) Inventors: Goon-Woo Kim, Cheonan-si (KR); Heui-Seog Kim, Asan-si (KR); Dong-Chun Lee, Asan-si (KR); Jeong-sam Lee, Cheonan-si (KR); Sung-Soo Lee, Asha-si (KR)

(21) Appl. No.: 13/228,966

(22) Filed: Sep. 9, 2011

(30) Foreign Application Priority Data
Oct. 27, 2010 (KR) 10-2010-0105240

(51) Int. Cl. H01L 21/78

(52) U.S. Cl. 438/463; 257/E21.599

(57) ABSTRACT

A method of fabricating a semiconductor device includes preparing a semiconductor wafer having a top surface and a bottom surface. The semiconductor wafer is loaded onto a wafer chuck, and the bottom surface of the loaded semiconductor wafer faces the wafer chuck. A groove is formed in the top surface of the loaded semiconductor wafer by irradiating a second laser onto the top surface, and a reforming region is formed in the loaded semiconductor wafer under the groove by irradiating a first laser through wafer chuck and bottom surface of the semiconductor wafer into a region in which the first laser is focused. The semiconductor wafer is unloaded from the wafer chuck. The bottom surface of the semiconductor wafer is ground to decrease a thickness of the semiconductor wafer. The semiconductor wafer is separated along the groove and the reforming region, thereby forming a plurality of unit chips.

### CROSS-REFERENCE TO RELATED APPLICATION

This application claims priority under 35 U.S.C. §119 from Korean Patent Application No. 10-2010-0105240 filed on Oct. 27, 2010 in the Korean Intellectual Property Office (KIPO), the contents of which are herein incorporated by reference in their entirety.

### BACKGROUND

1. Technical Field

Exemplary embodiments of the inventive concept are directed to sawing equipment and a method of sawing a wafer using the same by which both top and bottom surfaces of a wafer may be simultaneously processed.

2. Description of Related Art

With developments of highly efficient and highly integrated products, the wafer thickness is becoming increasingly smaller. Due to the reduction in wafer thickness, transferring wafers between process operations or between processes may be challenging.

### SUMMARY

Exemplary embodiments of the inventive concept provide a method of fabricating a semiconductor device including performing a grinding process after a dicing process.

Exemplary embodiments of the inventive concept also provide a method of fabricating a semiconductor device including irradiating different kinds of lasers to upper and lower portions of a semiconductor wafer.

Exemplary embodiments of the inventive concept also provide a method of fabricating a semiconductor device using semiconductor equipment capable of irradiating different kinds of lasers to upper and lower portions of a semiconductor wafer.

Exemplary embodiments of the inventive concept also provide a method and system by which both top and bottom surfaces of a bare wafer may be simultaneously processed to ensure good handling properties, prevent cracks, and shorten a process time.

The inventive concept is not limited to the above-mentioned exemplary embodiments, and other exemplary embodiments which are not be described will be clearly understood with reference to the following descriptions by those skilled in the art.

In accordance with an aspect of the inventive concept, a method of fabricating a semiconductor device is provided. The method includes preparing a semiconductor wafer having top and bottom surfaces. The semiconductor wafer is loaded on a wafer chuck. Here, the bottom surface of the loaded semiconductor wafer faces the wafer chuck. A groove is formed in the top surface of the loaded semiconductor wafer, and a reforming region is formed in the loaded semiconductor wafer. The reforming region is formed in the semiconductor wafer under the groove by focusing a first laser into the semiconductor wafer. Light from the first laser transmits through the wafer chuck and the bottom surface of the semiconductor wafer to the focused regions in the semiconductor wafer to reform the inside of the semiconductor wafer. The groove is formed by irradiating a second laser onto the top surface of the semiconductor wafer. The semiconductor wafer is unloaded from the wafer chuck.

In some embodiments, the wafer chuck may include a transparent material.

In another embodiment, the groove may wider than the reforming region.

In still another embodiment, the method may include grinding the bottom surface of the unloaded semiconductor wafer to decrease a thickness of the semiconductor wafer, forming a thinner semiconductor wafer. The reforming region may be unaffected by the decrease in semiconductor wafer thickness.

In yet another embodiment, the groove and the reforming region may be simultaneously formed.

The second laser may emit a light different from that of the first laser.

The first laser may be an infrared (IR) laser, and the second laser may be an ultraviolet (UV) laser.

In another embodiment, the method may include separating the semiconductor wafer along the groove and the reforming region to form a plurality of unit chips.

In yet another embodiment, the division of the semiconductor wafer may include adhering the thinner semiconductor wafer to an extension tape, and stretching the extension tape to separate the semiconductor wafer along the groove and the reforming region.

In accordance with another aspect of the inventive concept, a method of fabricating a semiconductor device includes loading a semiconductor wafer having a top surface and a bottom surface onto a top surface of a wafer chuck. A groove may be formed in the top surface of the loaded semiconductor wafer, and a reforming region may be formed under the groove in the semiconductor wafer. The semiconductor wafer may be unloaded from the wafer chuck. The bottom surface of the unloaded semiconductor wafer may be ground to decrease a thickness of the semiconductor wafer, forming a thinner semiconductor wafer. An extension tape may be adhered to the ground bottom surface of the semiconductor wafer. The extension tape may stretched to separate the semiconductor wafer along the groove and the reforming region, thereby forming a plurality of unit chips. The plurality of unit chips may be packaged, respectively.

In some embodiments, the semiconductor wafer may include a semiconductor substrate region, an integrated circuit forming region on the semiconductor substrate region, and an interconnection and pad forming region on the integrated circuit forming region. The interconnection and pad forming region may be provided on the top surface of the semiconductor wafer. The semiconductor wafer may include chip regions and cut regions between the chip regions. The groove may be formed in the cut region and extend into the semiconductor substrate region through the interconnection and pad forming region and the integrated circuit forming region, and the reforming region may be formed in the cut region under the groove in the semiconductor substrate region.

In another embodiment, the reforming region may be formed under the groove in the semiconductor wafer, and spaced apart from the groove.

In still another embodiment, the reforming region may be spaced apart from the bottom surface of the thinner semiconductor wafer.

In yet another embodiment, the reforming region may include one or more separated reforming regions.

In yet another embodiment, the reforming region may include one or more partially overlapping reforming regions.

In yet another embodiment, a part of the wafer chuck on which the semiconductor wafer is disposed is formed of a transparent material.

In accordance with another aspect of the inventive concept, a device for fabricating a semiconductor device may include a wafer chuck unit, a first dicing unit, and a second dicing unit. The wafer chuck unit may include a transparent wafer chuck for supporting a semiconductor wafer, a guard ring unit for supporting or fixing the wafer chuck, and a chuck moving unit for horizontally moving the guard ring unit and the wafer chuck. The first dicing unit may include a first laser head and a first head moving unit with a first motor unit for moving the first laser head in a horizontal or vertical direction. The first laser head may irradiate a first laser through the transparent wafer chuck to be focused on a region inside the semiconductor wafer, to form a reforming region in the focused region. The second dicing unit may include a second laser head for irradiating onto the semiconductor wafer a second laser different from the first laser, and a second head moving unit with a second motor unit for moving the second laser head horizontally and vertically. The first laser head and the second laser head may simultaneously irradiate the first and second lasers onto the semiconductor wafer.

In some embodiments, the guard ring unit may include an upper body and a lower body, a horizontal support unit, and a vertical support unit. The horizontal support unit may be disposed on the wafer chuck and may be installed in one of the upper body or the lower body. The horizontal support may move horizontally to fix the loaded semiconductor wafer. The vertical support unit may be installed in one of the lower body or the upper body. The vertical support unit may move vertically and horizontally, or may rotate and move vertically. The vertical support unit may contact a dummy region of a top surface of a semiconductor wafer loaded on the wafer chuck.

In some embodiments, the guard ring may include a first vacuum line in a lower part thereof and the wafer chuck may include a second vacuum line therein and one or more vacuum holes that connect the second vacuum line to a surface of the wafer chuck. The second vacuum line in the wafer chuck may connect to the first vacuum line in the guard ring unit, the first vacuum line may connect to a vacuum pump by a vacuum line connecting member. A semiconductor wafer loaded onto the wafer chuck may be fixed using a suction force provided by the one or more vacuum holes.

### BRIEF DESCRIPTION OF THE DRAWINGS

FIG. 1 is a flowchart illustrating a method of fabricating a semiconductor device according to an exemplary embodiment of the inventive concept.

FIG. 2A is a schematic diagram illustrating a unit for a dicing process according to an exemplary embodiment of the inventive concept.

FIG. 2B is a flowchart illustrating a semiconductor back-end process according to an exemplary embodiment of the inventive concept.

FIGS. 3A and 3B are plan views partially illustrating a semiconductor wafer according to an exemplary embodiment of the inventive concept.

FIGS. 4A to 4H are cross-sectional views illustrating a method of fabricating a semiconductor device according to an exemplary embodiment of the inventive concept.

FIG. 5A is a cross-sectional view illustrating a method of fabricating a semiconductor device according to another exemplary embodiment of the inventive concept.

FIG. 5B is a cross-sectional view illustrating a method of fabricating a semiconductor device according to still another exemplary embodiment of the inventive concept.

FIGS. 6A and 6B are cross-sectional views illustrating a semiconductor device prepared according to an exemplary embodiment of the inventive concept.

FIG. 7 is a diagram schematically illustrating a device for a dicing process according to an exemplary embodiment of the inventive concept.

FIG. 8 is a diagram schematically illustrating a device for a dicing process according to another exemplary embodiment of the inventive concept.

FIG. 9 is a diagram schematically illustrating a device for a dicing process according to still another exemplary embodiment of the inventive concept.

FIGS. 10A and 10B are diagrams schematically illustrating a wafer chuck unit according to an exemplary embodiment of the inventive concept.

FIGS. 11A and 11B are diagrams schematically illustrating a wafer chuck unit according to another exemplary embodiment of the inventive concept.

FIGS. 12A and 12B are diagrams schematically illustrating a wafer chuck unit according to another exemplary embodiment of the inventive concept.

FIGS. 13 to 16 are block diagrams schematically illustrating a semiconductor module, an electronic circuit board, a data storage device, and an electronic system including semiconductor devices according to exemplary embodiments of the inventive concept, respectively.

### DETAILED DESCRIPTION OF EXEMPLARY EMBODIMENTS

Various embodiments will now be described more fully with reference to the accompanying drawings in which some exemplary embodiments are shown. Embodiments of the inventive concepts may, however, be embodied in different forms and should not be construed as limited to the exemplary embodiments set forth herein.

It will be understood that when an element or layer is referred to as being “on,” “connected to” or “coupled to” another element or layer, it can be directly on, connected or coupled to the other element or layer or intervening elements or layers may be present. Like numerals refer to like elements throughout.

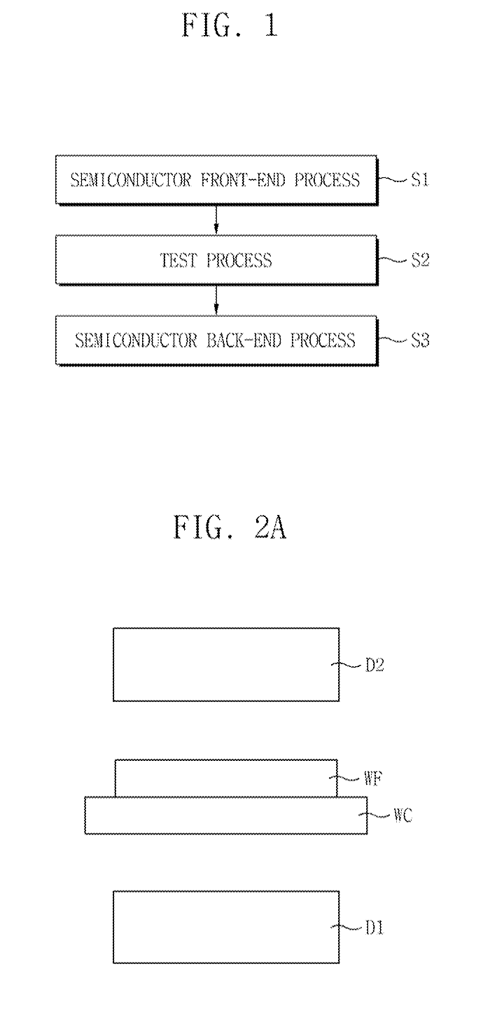

FIG. 1 is a flowchart schematically illustrating a method of fabricating a semiconductor device according to an exemplary embodiment of the inventive concept.

Referring to FIG. 1, a semiconductor front-end process for fabricating an integrated circuit using elements such as a MOS transistor, a resistor, and a capacitor on a semiconductor wafer may be performed at step S1. The semiconductor wafer may be a silicon wafer having top and bottom surfaces facing each other. Further, an integrated circuit may be foamed on the top surface of the semiconductor wafer. The semiconductor wafer may include chip regions and a scribe lane region between the chip regions.

Subsequently, at step S2, a test process of measuring the electrical characteristics of an integrated circuit or elements constituting the integrated circuit may be performed. Afterwards, at step S3, a semiconductor back-end process may be performed. The semiconductor back-end process may include decreasing a thickness of the semiconductor wafer, forming a plurality of unit chips by separating the chip regions from the semiconductor wafer, and packaging the separated unit chips.

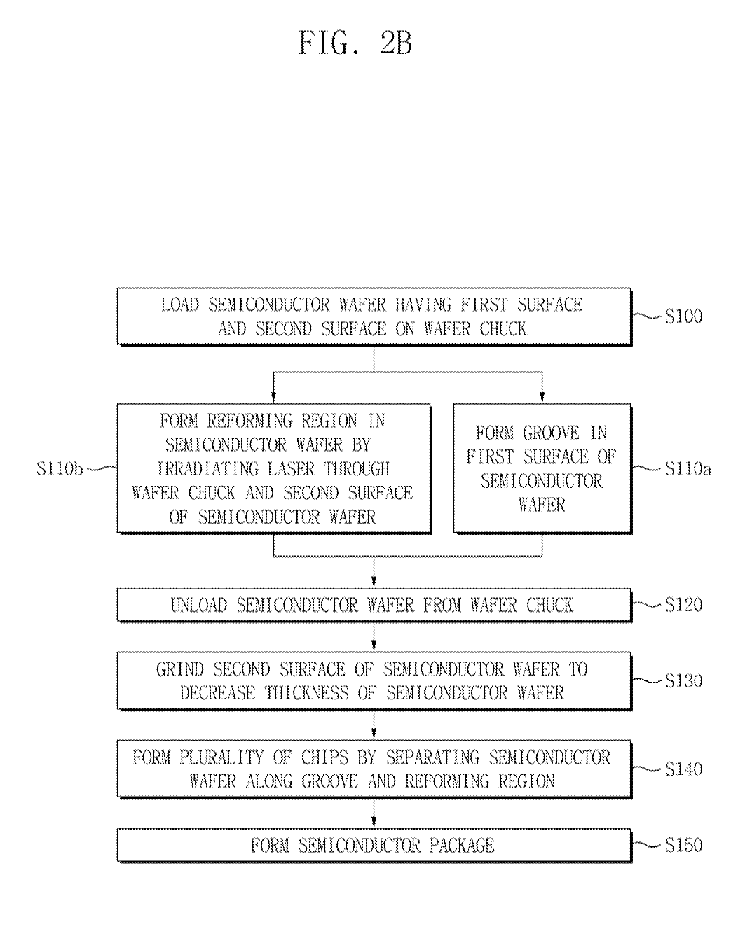

Hereinafter, the semiconductor back-end process of step S3 according to an exemplary embodiment of the inventive concept will be described in further detail with reference to FIGS. 2A and 2B. Here, FIG. 2A is a schematic diagram partially illustrating semiconductor equipment for fabricating a semiconductor device according to an exemplary embodiment of the inventive concept. FIG. 2B is a flowchart illustrating the semiconductor back-end process of step S3 of FIG. 1 in detail.

Referring to FIGS. 2A and 2B, a semiconductor wafer WF having top and bottom surfaces facing each other may be loaded on a wafer chuck WC at step S100. The top surface of the semiconductor wafer WF may be a surface on which an integrated circuit will be formed. The bottom surface of the loaded semiconductor wafer WF may face the wafer chuck WC.

A first dicing unit D1 may be provided opposite to the bottom surface of the loaded semiconductor wafer WF with the wafer chuck WC in between. A second dicing unit D2 may be provided opposite to and facing the top surface of the loaded semiconductor wafer WF.

A groove may be formed in the top surface of the semiconductor wafer WF using the second dicing unit D2 at step S110a.

A reforming region may be formed in the semiconductor wafer under the groove by using the first dicing unit D1 to irradiate a laser through the wafer chuck and the bottom surface of the semiconductor wafer at step S110b.

The formation of the groove in step S110a and the formation of the reforming region in step S110b may be performed simultaneously. Although not shown in the figure, the first and second dicing units D1 and D2 may be parts of a same piece of equipment.

Subsequently, the semiconductor wafer with the groove and reforming region may be unloaded at step S120.

Subsequently, to decrease the thickness of the semiconductor wafer, the bottom surface of the semiconductor wafer may be ground at step S130, to form a thinner semiconductor wafer.

A plurality of unit chips may be formed by separating the thinner semiconductor wafer at step S140. In detail, the plurality of unit chips may be formed by cutting the semiconductor wafer along the groove and the reforming region. Subsequently, at step S150, a semiconductor package may be formed using the unit chips.

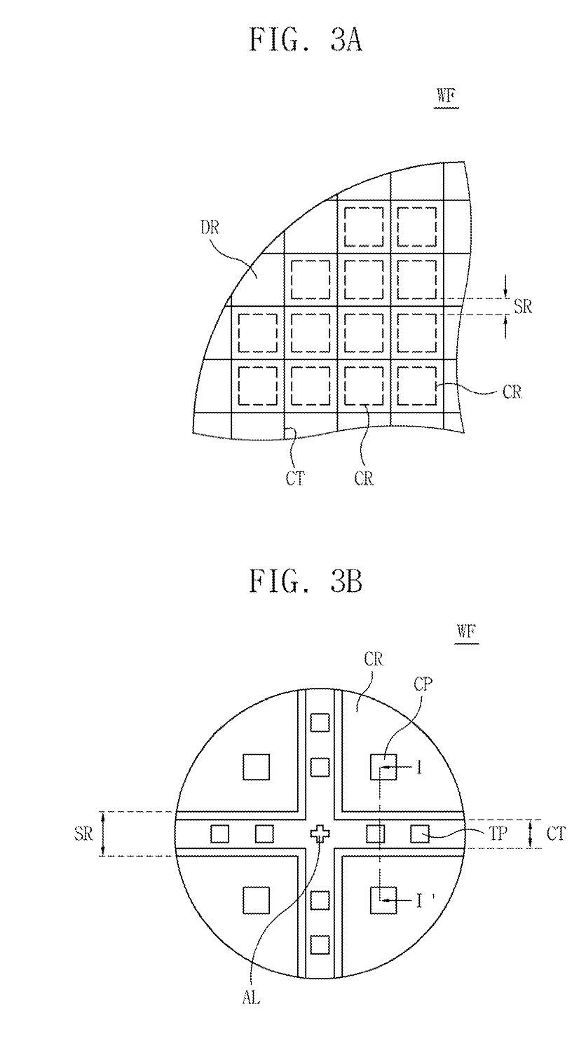

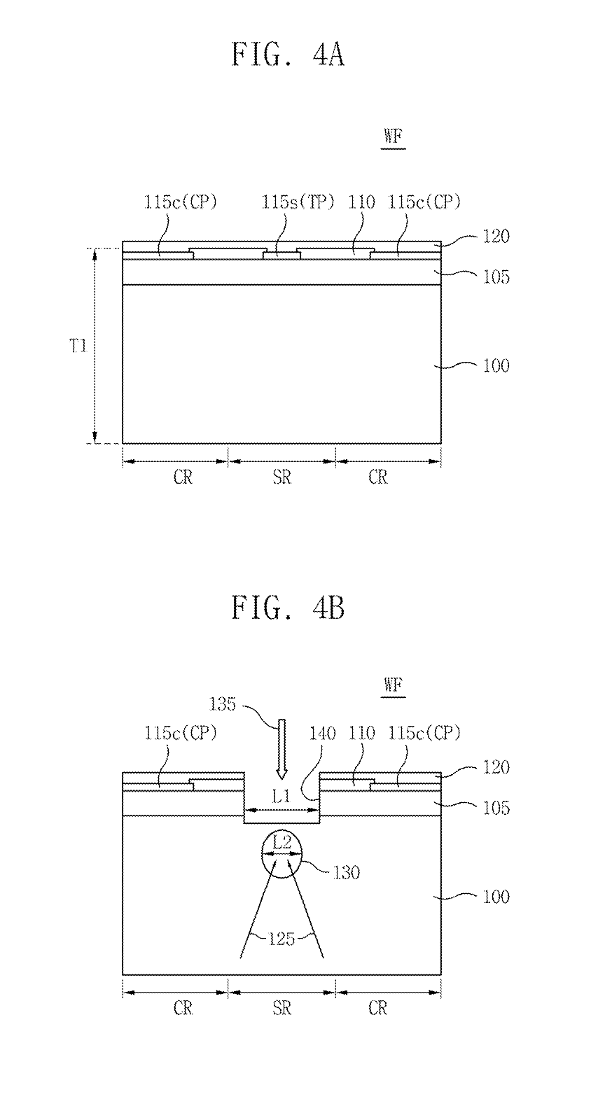

FIG. 3A is a plan view of a part of the semiconductor wafer, FIG. 3B is an enlarged view of a part of FIG. 3A, and FIGS. 4A to 4H are cross-sectional views of a region taken along line I-I′ of FIG. 3. Methods of fabricating a semiconductor device according to exemplary embodiments of the inventive concept will be described in further detail with reference to FIGS. 2A, 2B, 3A, 3B, and 4A to 4H below.

Referring to FIGS. 3A, 3B and 4A, a semiconductor wafer WF having top and bottom surfaces may be provided. The semiconductor wafer WF may include a semiconductor substrate 100, and a circuit forming region 105 and an interconnection and pad forming region 110, which are sequentially stacked on the semiconductor substrate 100. The combined semiconductor substrate 100, circuit forming region 105 and an interconnection and pad forming region 110 may have a first thickness T1. Here, the interconnection and pad ft:liming region 110 may be provided on the top surface of the semiconductor wafer WF.

The semiconductor substrate 100 may be formed of silicon. The circuit forming region 105 may be formed on the semiconductor substrate 100, and may include integrated circuits. The interconnection and pad forming region 110 may include interconnections and pads electrically connecting the integrated circuits.

Referring to FIG. 3A, the semiconductor wafer 100 may include a plurality of chip regions CR and scribe lane regions SR between the plurality of chip regions CR. A cut region CT may be provided in each of the scribed lane regions SR.

In addition, a dummy region DR in which the chip regions CR are not formed may be provided along an edge of the semiconductor wafer WF.

Referring to FIG. 3B, chip pads CP 115c for providing electrical signals to a semiconductor integrated circuit may be provided in the chip regions CR of the semiconductor wafer WF. The pads 115c may be input/output pads for inputting and outputting an electrical signal such as a clock, address or data signal, or may be power/ground pads.

Test pads TP 115s for measuring electrical and processing characteristics of a semiconductor chip may be provided in the scribe lane region SR of the semiconductor wafer WF. In addition, an alignment key AL may be provided where perpendicular scribe lane regions SR of the semiconductor wafer WF cross each other.

Referring to FIG. 4A, a surface protection layer 120 may be formed that covers the top surface of the semiconductor wafer WF. The surface protection layer 120 may be formed by coating an aqueous solution on the top surface of the semiconductor wafer WF. The surface protection layer 120 may be formed of a polyvinyl-based aqueous material.

Referring to FIGS. 2A, 2B, 3A, 3B and 4B, the semiconductor wafer WF may be loaded onto a wafer chuck WC at step S100. Here, the bottom surface of the loaded semiconductor wafer WF may face the wafer chuck WC. Thus, the top surface of the semiconductor wafer WF may be exposed. The wafer chuck WC may be formed of a transparent substrate capable of transmitting visible or infra-red (IR) light. For example, the wafer chuck WC may be formed of a material such as glass or quartz.

A groove 140 may be formed in the top surface of the semiconductor wafer WF using the second dicing unit D2 at step S110a. The groove 140 may be formed by irradiating an ultra-violet (UV) laser 135 from the second dicing unit D2. The groove 140 may be formed in the scribe lane region SR. A width L1 of the groove 140 may be defined as a width of the cut region CT. The width L1 of the groove 140 may be less than that of the scribe lane region SR to avoid misalignments.

The groove 140 may be formed through the interconnection and pad forming region 110, and the circuit forming region 105. Further, the bottom surface of the groove 140 may extend into the semiconductor substrate 100.

A reforming region 130 may be formed under the groove 140 in the semiconductor substrate 100 using the first dicing unit D1.

The reforming region 130 may be formed using a laser capable of transmitting through a silicon substrate, such as an IR laser 125. In other words, the IR laser 125 irradiated from the first dicing unit D1 may transmit through the wafer chuck WC and the bottom surface of the semiconductor wafer WF, and be focused in a region of the semiconductor substrate 100 disposed under the groove 140. As a result, the focused region of the semiconductor substrate, i.e. the region in which the IR laser 125 is focused, may be transformed into the reforming region 130. The reforming region 130 may be an amorphous region. Thus, the reforming region 130 may have a reduced mechanical strength with respect to other parts of the semiconductor substrate region 100 into which the IR laser 125 was not irradiated. The reforming region 130 and the groove 140 may be simultaneously formed in the semiconductor substrate region 100. For example, referring to FIG. 2A, when the IR laser 125 and the UV laser 135 are simultaneously irradiated from the first and second dicing units D1 and D2, the wafer chuck WC may be moved, and the groove 140 and the reforming region 130 may be simultaneously formed.

In some embodiments, the reforming region 130 and the groove 140 may be separated from each other.

In some embodiments, the groove 140 may be formed to a first width L1, and the reforming region 130 may be formed to a second width L2 less than the first width L1.

The surface protection layer 120 may prevent contamination of the chip regions CR from contaminants generated when the groove 140 is foamed.

Afterwards, at step S120, the semiconductor wafer WF having the reforming region 130 and the groove 140 may be unloaded from the wafer chuck WC S120.

Subsequently, the remaining surface protection layer 120 on the semiconductor wafer WF may be removed. Since the surface protection layer 120 may be formed of an aqueous material, it may be removed with deionized water.

Referring to FIGS. 2B, 3A, 3B and 4C, a back-grinding film 145 may be formed on the top surface of the semiconductor wafer WF. The back-grinding film 145 may serve to protect the top surface of the semiconductor wafer WF while the bottom surface of the semiconductor wafer WF is being ground.

Referring to FIGS. 2B, 3A, 3B, and 4D, the bottom surface of the semiconductor wafer WF may be ground by a back-grinding process at step S130. Accordingly, a thickness of the ground semiconductor wafer WF′ may be decreased to a second thickness T2, thinner than the initial first thickness T1.

The reforming region 130 may be unaffected by the back-grinding process and may remain in the thinner semiconductor wafer WF′. In addition, the reforming region 130 may be spaced apart from the bottom surface S2 of the thinner semiconductor wafer WF′.

Referring to FIGS. 3A, 3B, and 4E, a base film 150 may be prepared. The base film 150 may be formed of an olefin-based material or a polyethylene-based material.

An extension tape 155 may be formed on the base film 150. The extension tape 155 may include a die-attach film (DAF).

The bottom surface of the thinner semiconductor wafer WF′ may be adhered to the extension tape 155.

An edge of the extension tape 155 may be fixed by a tape support 160. Subsequently, as shown in FIG. 4F, the back-grinding film 145 may be removed.

Referring to FIGS. 2B, 3A, 3B and 4G, the extension tape 155 may be stretched. A planar area of the extension tape 155 may be increased, that is, the extension tape 155 may be stretched from the center of the semiconductor wafer WF to the wafer edges X1 and X2. For example, when the tape support 160 is fixed, and a pressure P is applied to the base film 150 in a direction normal to the semiconductor wafer WF′, the extension tape 155 fixed by the tape support 160 may stretch. Accordingly, as the extension tape 155 stretches, increasing a distance L3 between the chip regions CR, the semiconductor wafer WF′ may separate along the groove 140 and the reduced strength reforming region 130.

Referring to FIG. 4H, after the semiconductor wafer WF′ is separated, the extension tape 155 may continue to stretch and be eventually cut. Thus, the extension tape 155 may remain as adhesive patterns 155a on the bottoms of the separated semiconductor wafers, respectively.

Accordingly, the chip regions of the semiconductor wafer may be separated from each other, thereby forming a plurality of unit chips CH. Each unit chip CH may include a thinner semiconductor substrate 100a, a circuit forming region 105a, and an interconnection and pad forming region 110a. In addition, each unit chip CH may include the adhesive pattern 155a remaining on the bottom surface of the semiconductor substrate 100a. Subsequently, the unit chips CH may be separated from the base film 150.

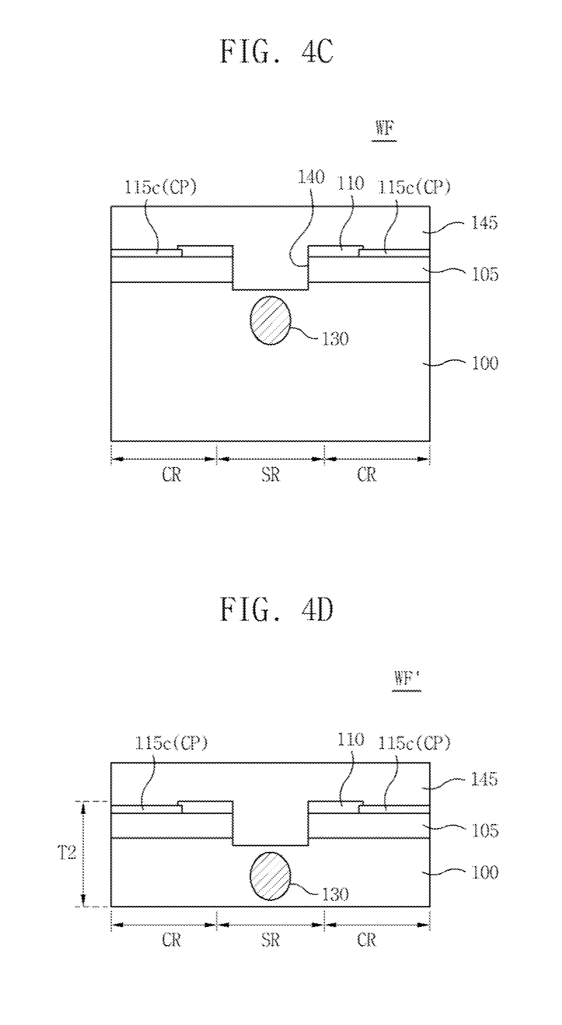

While the reforming region 130 is formed as a single region in the above description, embodiments of the inventive concept are not limited thereto. For example, to cut a thicker wafer, as shown in FIG. 5A, a plurality of reforming regions 130a and 130b spaced apart in different regions may be formed. In other words, a first IR laser 225a may be focused on the first reforming region 130a of the semiconductor wafer, and a second IR laser 225b may be focused on the second reforming region 130b of the semiconductor wafer, separate from the first reforming region 130a. Accordingly, the reforming regions 130a and 130b may be separated from each other.

On the other hand, as shown in FIG. 5B, a plurality of reforming regions 130a and 130b partially overlapping each other on a vertical line may be formed. For example, the first IR laser 225a may be focused on the semiconductor substrate 100 where the first reforming region 130a will be formed, and the second IR laser 225b may be focused where the second reforming region 130b partially overlapping the first reforming region 130a will be formed. Thus, the reforming regions 130a and 130b may partially overlap each other in a vertical direction.

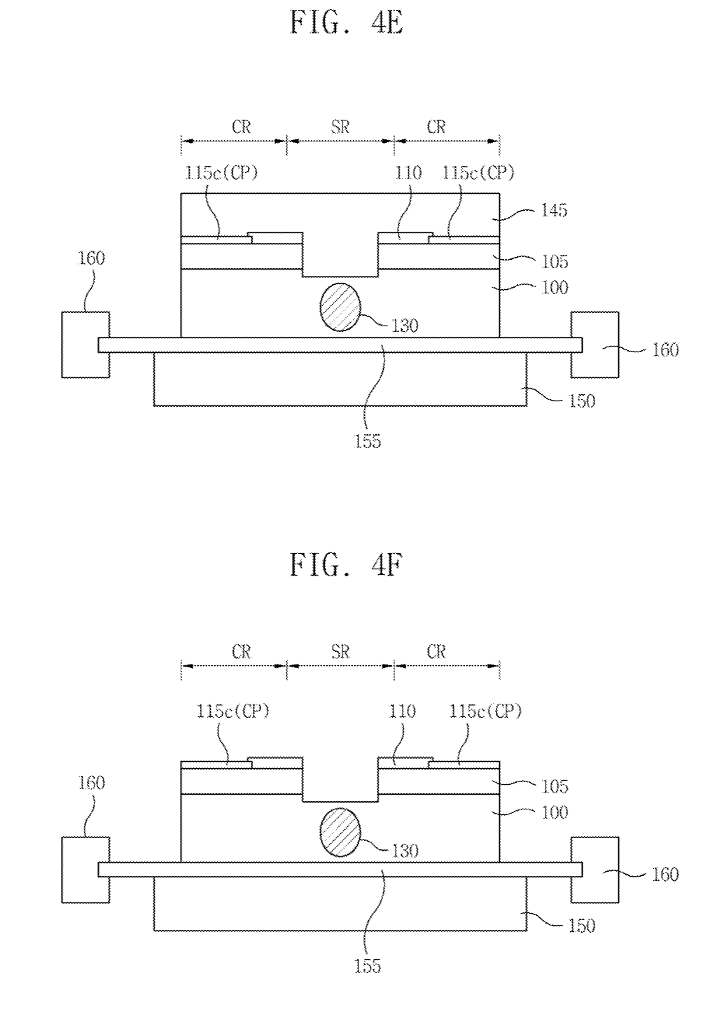

Subsequently, a semiconductor package process may be performed on the plurality of unit chips CH formed as described with reference to FIG. 4H. Hereinafter, a semiconductor package process according to an exemplary embodiment of the inventive concept will be described with reference to FIG. 6A.

Referring to FIGS. 4H and 6A, a unit chip CH may be mounted on a package substrate 300. The unit chip CH may include one or more pads 115s formed in the interconnection and pad forming region 110a. The package substrate 300 may be a printed circuit board. Alternatively, the package substrate 300 may be a substrate for a semiconductor package, for example, formed of ceramic or glass.

A bonding wire 310 for electrically connecting the package substrate 300 to the unit chip CH may be formed. Thus, a semiconductor package having a wire bonding structure may be formed. In FIG. 6A, a bond finger on the package substrate 300 is omitted.

A semiconductor package according to another exemplary embodiment of the inventive concept will be described with reference to FIG. 6B.

In the exemplary embodiments described with reference to FIGS. 4A to 4H, a semiconductor wafer WF having pads 115s formed in the interconnection and pad forming region 110 is described, but embodiments of the inventive concept are not limited thereto. In other words, the processes described with reference to FIGS. 4A to 4H may be performed on a semiconductor wafer having solder bumps 115b in the interconnection and pad forming region 110. As a result, a unit chip CH′ including a thinner semiconductor substrate 100b, a circuit forming region 105b, and an interconnection and pad forming region 110b having the solder bumps 115b may be formed.

As shown in FIG. 6B, the unit chip CH′ may be mounted in a flip-chip type mount on a package substrate 320. In other words, the unit chip CH′ may be mounted on the package substrate 320 to electrically connect the solder bumps 115b of the unit chip CH′ to the package substrate 320.

Hereinafter, semiconductor equipment for forming the reforming region 130 and the groove 140 in the semiconductor back-end process described above will be described.

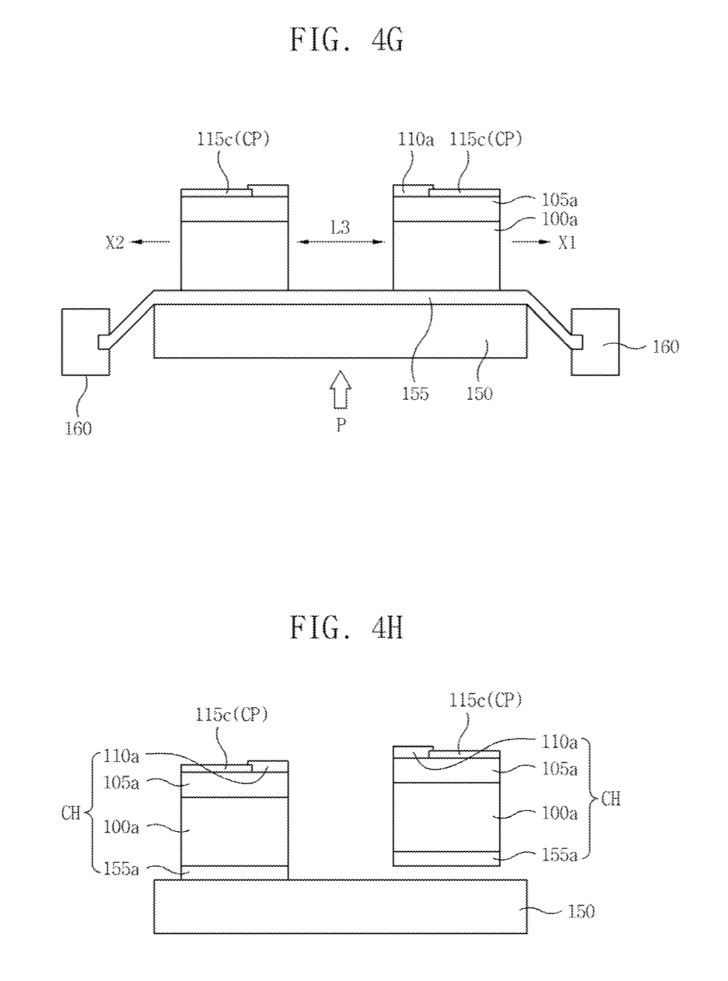

First, semiconductor equipment according to an exemplary embodiment of the inventive concept will be described with reference to FIG. 7.

Referring to FIG. 7, the semiconductor equipment may include a wafer chuck unit 400, a first dicing unit 450, and a second dicing unit 490.

The wafer chuck unit 400 may include a wafer chuck 410, a guard ring unit 415 for supporting or fixing the wafer chuck 410, and a chuck moving unit 420.

The wafer chuck 410 may be a transparent substrate capable of transmitting visible or infra-red light. For example, the wafer chuck 410 may be formed of a material such as glass or quartz. A semiconductor wafer WF may be loaded on the wafer chuck 410. The wafer chuck 410 may wider than the semiconductor wafer WF loaded thereon. The chuck moving unit 420 may include an element such as a servo motor to move the guard ring unit 415 and the wafer chuck 410 in a horizontal direction, for example, forward and backward or left and right.

The first dicing unit 450 may include a first laser head 460, a first head moving unit 465, and a first motor unit 470. The first motor unit 470 may include a servo motor.

The first head moving unit 465 and the first motor unit 470 may move the first laser head 460 in a horizontal or vertical direction. As described with reference to FIG. 4B, a first laser 475 irradiated from the first laser head 460 may transmit through the wafer chuck 410 and be focused inside the semiconductor wafer WF. As a result, a reforming region R may be formed in the focused region of the semiconductor wafer WF. The first laser 475 may be an IR laser.

The second dicing unit 490 may be, as described with reference to FIG. 4B, a unit for forming a groove G in the semiconductor wafer WF. For example, the second dicing unit 490 may include any one of a blade dicing unit, a plasma dicing unit, a wire dicing unit, and a water jet dicing unit. Alternatively, the second dicing unit 490 may include a laser system capable of irradiating a second laser having different characteristics from the first laser 475. For example, the second laser may be a laser capable of cutting a pattern in a material such as a metal. For example, the second laser may be a UV laser.

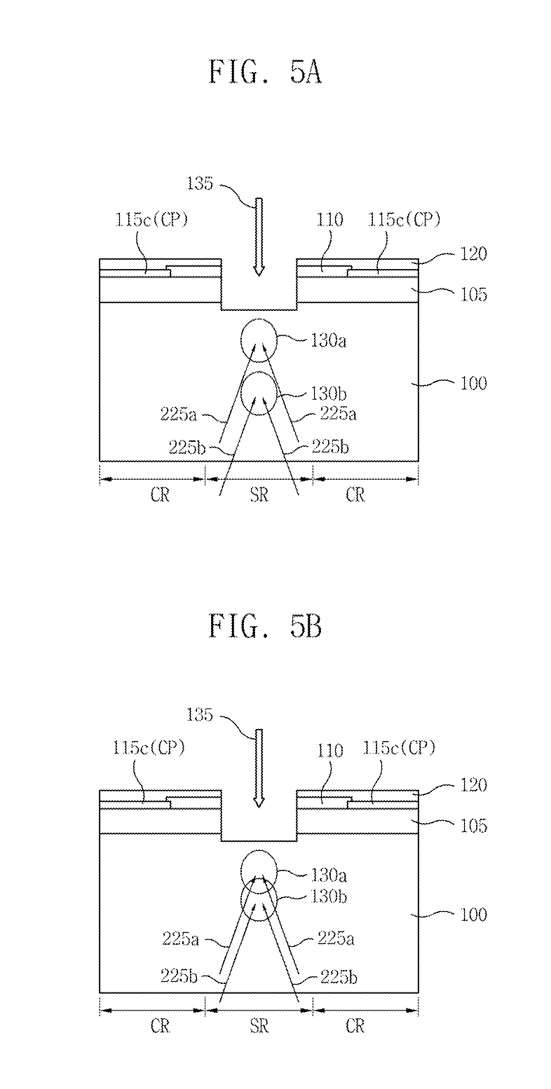

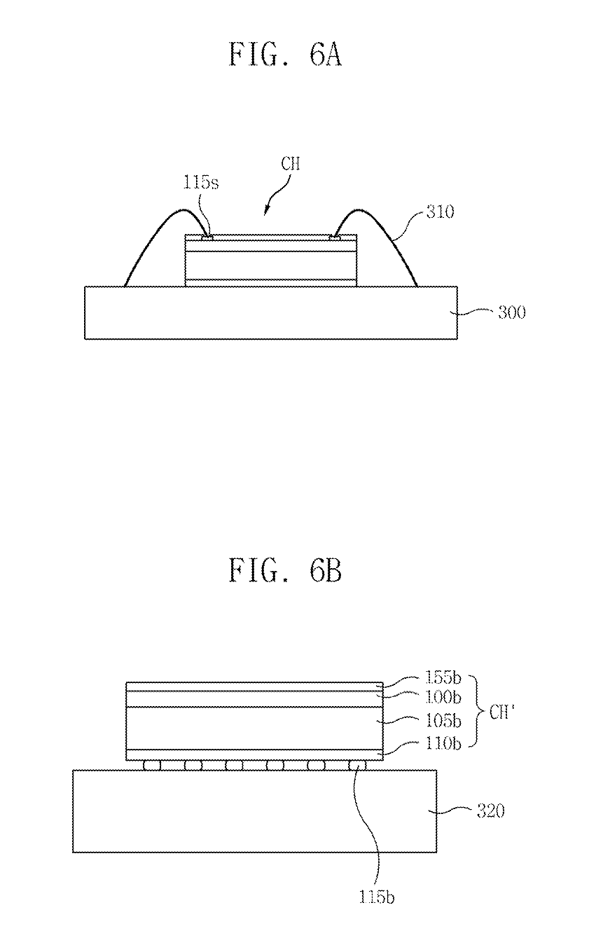

Semiconductor equipment including a second laser different from the first laser 475 will be described with reference to FIGS. 8 and 9, respectively.

Referring to FIG. 8, the semiconductor equipment may include first and second dicing units 450 and 500 disposed above and below a wafer chuck 410. The semiconductor equipment may include a wafer chuck unit 400. The wafer chuck unit 400 and the first dicing unit 450 may be the same as those described in FIG. 7, and thus detailed descriptions thereof will be omitted.

The second dicing unit 500 may include a second laser head 510 for irradiating a second laser 525 different from the first laser 475, a second head moving unit 515, and a second motor unit 520. The second head moving unit 515 and the second motor unit 520 may move the second laser head 510 horizontally and vertically.

Semiconductor equipment including a laser system according to still another exemplary embodiment of the inventive concept will be described with reference to FIG. 9.

Referring to FIG. 9, the semiconductor equipment may include first and second dicing units 450v and 500v disposed on the left and right of a wafer chuck unit 400v. The wafer chuck unit 400v may include a wafer chuck 410v, a guard ring unit 415v for supporting or fixing the wafer chuck 410v, and a chuck moving unit 420v. The wafer chuck 410v may be a substrate transparent to visible and IR light.

A semiconductor wafer WF may be loaded on the wafer chuck 410v. The chuck moving unit 420v may include a unit such as a servo motor to vertically displace the guard ring unit 415v, the wafer chuck 410v, and the semiconductor wafer WF′ loaded on the wafer chuck 410. The first dicing unit 450v may include a first laser head 460v and a first head moving unit 465v. The second dicing unit 500v may include a second laser head 510v for irradiating a second laser 525v different from the first laser 475v, and a second head moving unit 515v.

The first and second dicing units 450v and 500v, and the wafer chuck unit 400v may be disposed on a piece of equipment 550.

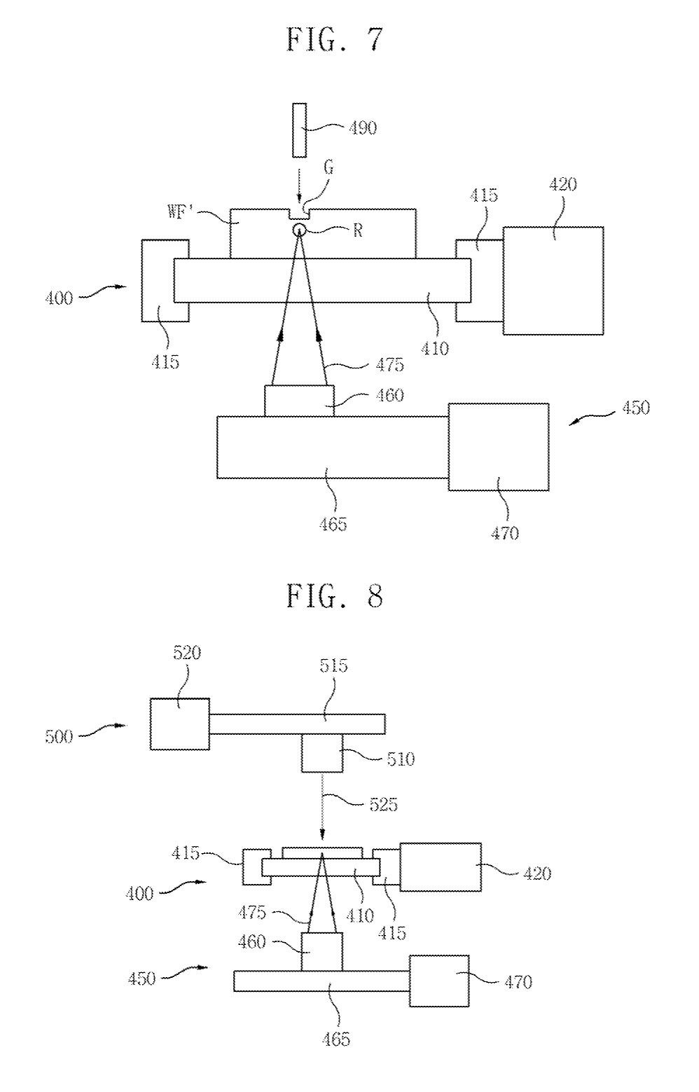

FIG. 10A is a plan view illustrating the guard ring unit 415 and the wafer chuck 410 of the wafer chuck unit 400 in detail, and FIG. 10B is a cross-sectional view illustrating the guard ring unit 415 and the wafer chuck 410.

Referring to FIGS. 10A and 10B, the guard ring unit 415 may include a guard ring lower body 415a, a guard ring upper body 415b, and a horizontal support unit 600. The guard ring upper body 415b may be formed on the guard ring lower body 415a. The wafer chuck 410 may be fixed to or supported by the guard ring unit 415.

The guard ring unit 415 may include the horizontal support unit 600 which can be moved horizontally. The horizontal support unit 600 may be disposed on the wafer chuck 410, and may move horizontally to horizontally support or fix the loaded semiconductor wafer WF′. The horizontal support unit 600 may be driven by a small servo motor connected to or installed in the guard ring lower body 415a or the guard ring upper body 415b.

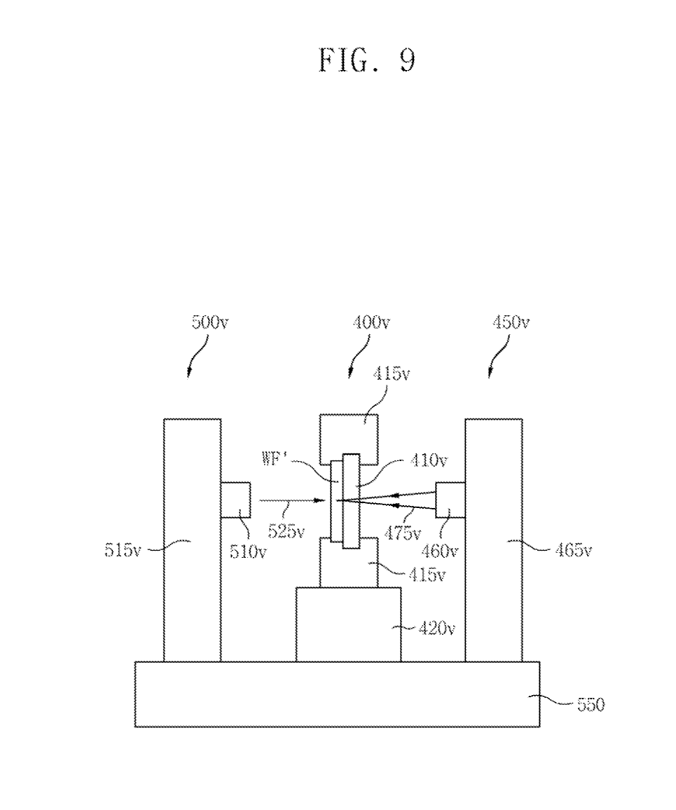

In addition, as shown in FIGS. 11A and 11B, the guard ring unit 415 may include a vertical support unit 610 connected to or installed in either the guard ring lower body 415a or the guard ring upper body 415b. The vertical support unit 610 may be a clamper. The vertical support unit 610 may move vertically and horizontally, or may rotate and move vertically. Thus, the vertical support unit 610 may be in contact with the top surface of the semiconductor wafer WF′, and may fix the semiconductor wafer WF′. Here, the part of the semiconductor wafer WF′ in contact with the vertical support unit 610 may be the dummy region DR described in FIG. 3A. Thus, the horizontal and vertical support units 600 and 610 may fix the semiconductor wafer WF′ without influencing the dicing process.

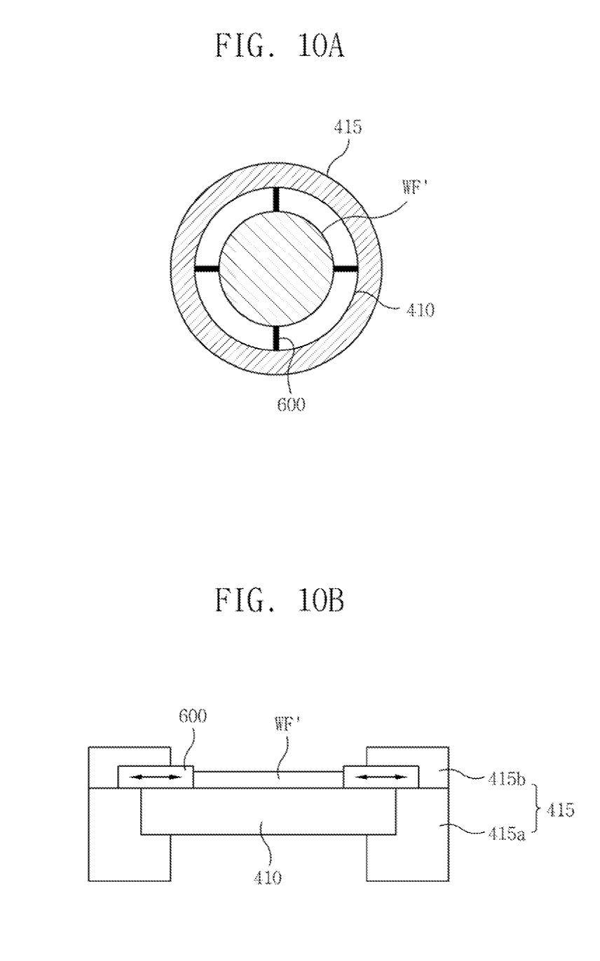

FIG. 12A is a cross-sectional view illustrating a guard ring unit and a wafer chuck according to yet another exemplary embodiment of the inventive concept, and FIG. 12B is a plan view illustrating the wafer chuck of FIG. 12A.

Referring to FIGS. 12A and 12B, a guard ring unit 730 may include a guard ring lower body 730a and a guard ring upper body 730b. A vacuum line 735 may be provided in the guard ring lower body 730a.

A wafer chuck 710 supported by or fixed to the guard ring unit 730 may be provided. The wafer chuck 710 may have a vacuum line 720 therein, and may further include one or more vacuum holes 715 that connect the vacuum line 720 to a surface of the wafer chuck 710. The vacuum line 720 in the wafer chuck 710 may connect to the vacuum line 735 in the guard ring unit 730. Further, the vacuum line 735 of the guard ring unit may be connected to a vacuum pump 750 by a vacuum line connecting member 760. Thus, the wafer WF′ loaded on the wafer chuck 710 may be fixed using a suction force provided by the vacuum hole 715.

The wafer chuck 710 may be formed of a transparent substrate, and methods of fabricating a semiconductor device according to exemplary embodiments of the inventive concept such as those described above may be applied to such a unit.

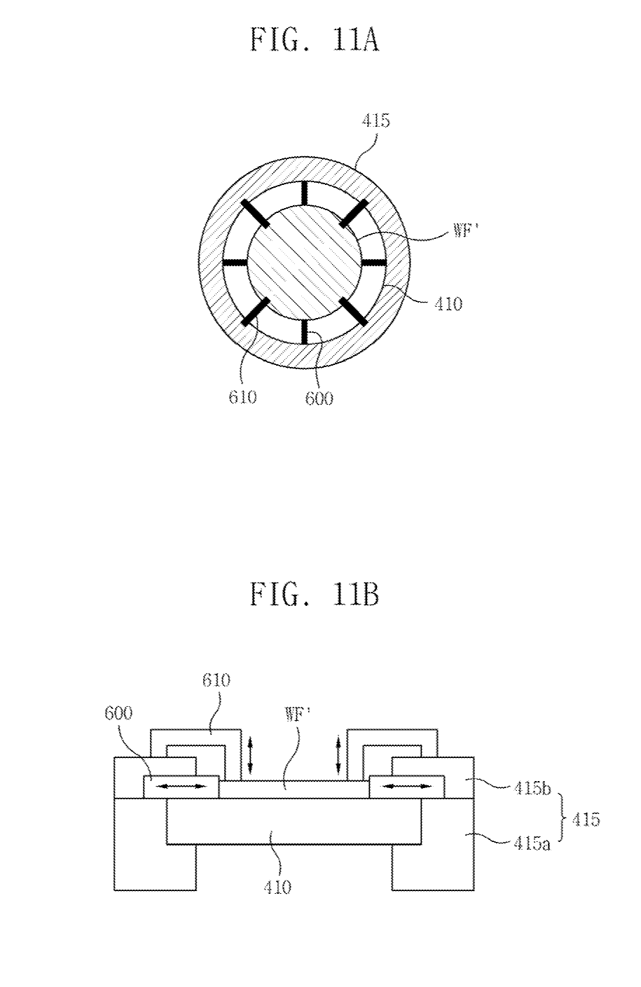

FIG. 13 is a diagram schematically illustrating a semiconductor module including a semiconductor device or package according to another embodiment of the inventive concept. Referring to FIG. 13, a semiconductor module 810 on which is mounted a semiconductor package formed according to an embodiment of the inventive concept includes a module substrate 811, a plurality of semiconductor devices 812 disposed on the module substrate 811, and module contact terminals 813 which are formed side by side at one edge of the module substrate 811 and are electrically connected to the semiconductor devices 812. The module substrate 811 may be a printed circuit board (PCB). Both surfaces of the module substrate 811 may be used. In other words, the semiconductor devices 812 may be disposed on both top and bottom surfaces of the module substrate 811. FIG. 13 shows eight semiconductor devices 812 disposed on the top surface of the module substrate 811, but this an exemplary, non-limiting embodiment for illustrative purposes. Further, the semiconductor module 811 may include a separate controller or chip set to control the semiconductor devices or packages 812. Accordingly, any number of semiconductor devices 812 such as those shown in FIG. 13 may be part of a semiconductor module 810. At least one of the semiconductor devices 812 may include a MOS transistor according to an exemplary embodiment of the inventive concept. The module contact terminals 813 may be formed of an antioxidant metal. The module contact terminals 813 may be set according to a specification of the semiconductor module 810. Therefore, the number of the module contact terminals 813 shown in FIG. 13 is exemplary and non-limiting, and may vary in other embodiments.

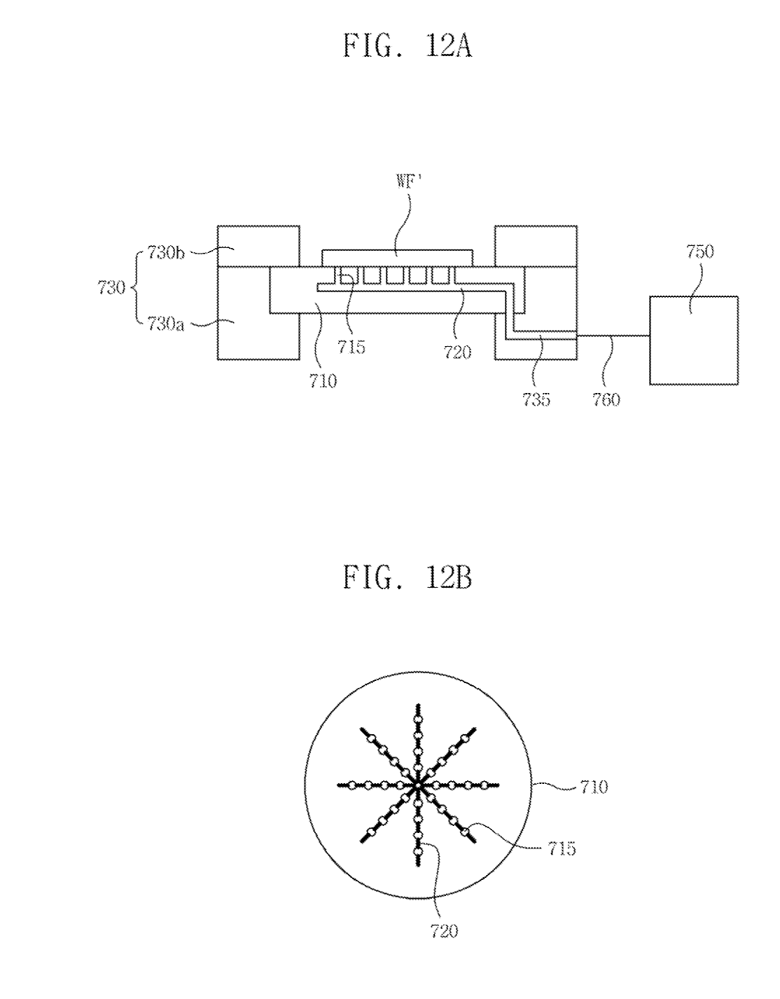

FIG. 14 is a block diagram schematically illustrating an electronic circuit board including a semiconductor package according to an embodiment of the inventive concept. Referring to FIG. 14, an electronic circuit board 820 according to an exemplary embodiment of the inventive concept includes a microprocessor 822 disposed on a circuit board 821, a main storage circuit 823 and a supplementary storage circuit 824, both of which communicate with the microprocessor 822, an input signal processing circuit 825 for sending a command to the microprocessor 822, an output signal processing circuit 826 for receiving a command from the microprocessor 82, and a communicating signal processing circuit 827 for sending and receiving electrical signals to and from other circuit boards. It can be understood that the arrows refer to pathways along which the electrical signals may be transmitted.

The microprocessor 822 may receive and process various electrical signals and output the processed results, and control other elements of the electrical circuit board 820. The microprocessor 822 may be considered, for example, a central processing unit (CPU), and/or a main controller (MCU). The main storage circuit 823 may temporarily store data before and after processing or data frequently used by the microprocessor 822. The main storage circuit 823 may be composed of a semiconductor memory device for a high speed response. In detail, the main storage circuit 823 may be a semiconductor memory device such as a cache, and may be composed of a static random access memory (SRAM), a dynamic random access memory (DRAM), a resistive random access memory (RRAM), or other applied semiconductor memory devices thereof, for example, a utilized RAM, a ferroelectric RAM, a fast cycle RAM, a phase changeable RAM, a magnetic RAM, or any other semiconductor memory device. In addition, the main storage circuit 823 may include a volatile or non-volatile random access memory.

The supplementary storage circuit 824 is a large-capacity memory device, which may be a non-volatile semiconductor memory such as a flash memory, or a magnetic hard disk drive. Alternatively, the supplementary storage circuit 824 may be a compact disk drive. The supplementary storage circuit 824 may be used when a large data storage capacity is needed, rather than when a high access speed is desired, as compared to the main storage circuit 823. The supplementary storage circuit 824 may include a non-volatile memory device. The input signal processing circuit 825 may convert an external command into an electrical signal, or transmit an electrical signal received from an external source to the microprocessor 822. The command or electrical signal received from the external source may be an operating command, an electrical signal to be processed, or data to be stored. The input signal processing circuit 825 may be, for example, a terminal signal processing circuit processing a signal received from a keyboard, a mouse, a touch pad, an image recognition device, or various other sensors, or may be an image signal processing circuit that processes an image signal received from a scanner, camera, or various other sensors or signal interfaces. The input signal processing circuit 825 may include at least one semiconductor module 810. The output signal processing circuit 826 may transmit the electrical signal processed in the microprocessor 822 to an external source. For example, the output signal processing circuit 826 may be a graphics card, an image processor, an optical transformer, a beam panel card, or an interface circuit having various functions. The output signal processing circuit 826 may include a semiconductor module 810. The communication circuit 827 may directly transmit and receive an electrical signal to and from another electronic system or circuit board, bypassing the input signal processing circuit 825 and the output signal processing circuit 826. For example, the communication circuit 827 may be a modem of a personal computer system, a LAN card, or any other interface circuit. The communication circuit 827 may include a semiconductor module 810 according to an embodiment of the inventive concept.

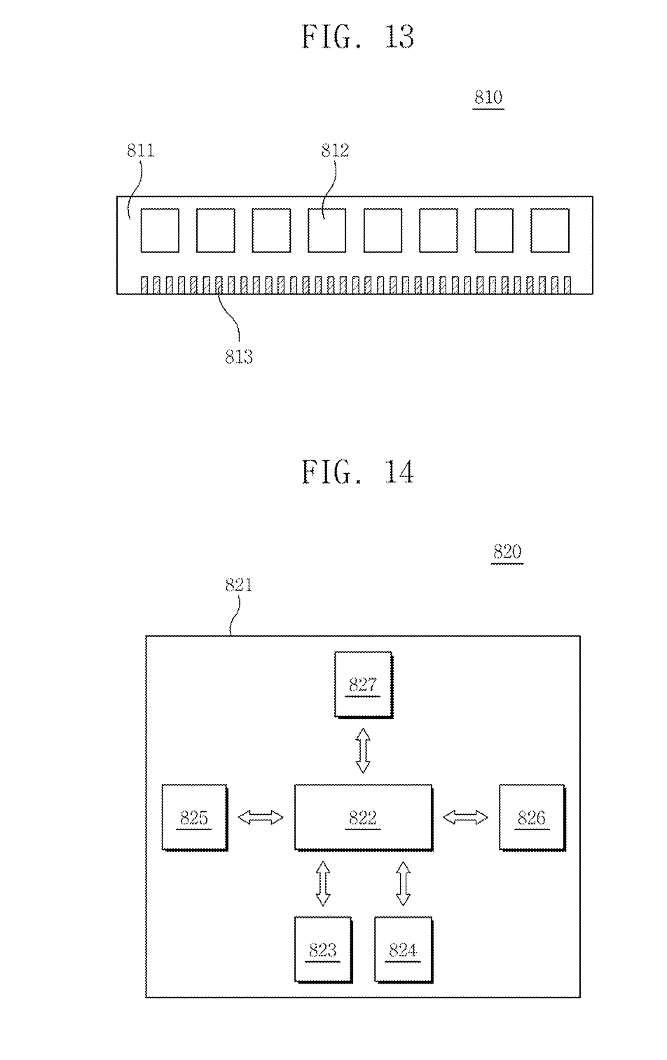

FIG. 15 is a block diagram illustrating a data storage device including a semiconductor package according to another embodiment of the inventive concept. Referring to FIG. 15, the data storage device may include a solid state disk (SSD) 830. An SSD 830 is a semiconductor device for storing data. The SSD 830 is faster, and has a lower mechanical delay or failure rate and generates less heat and noise than a hard disk drive (HDD). Further, an SSD 830 may be smaller and lighter than an HDD. The SSD 830 may be used in a laptop computer, a desktop PC, an MP3 player, or a portable storage device. The SSD 830 may include a non-volatile memory 831, a buffer memory 832, and a controller 833.

The non-volatile memory 831 may be a resistive memory. The non-volatile memory 831 may include a data storage element such as a phase change material pattern, a magnetic tunnel junction (MTJ) pattern, a polymer pattern and an oxide pattern. The buffer memory 832 may include a volatile memory. The volatile memory may be a DRAM or SRAM. The buffer memory 832 may exhibit a faster operating speed than the non-volatile memory 831. The controller 833 includes an interface 834 connected to a host 835. The interface 834 is connected to the host 835 and thus may send and receive electrical signals such as data. The interface 834 may be a Serial Advanced Technology Attachment (SATA) interface, an Integrated Drive Electronics (IDE) interface, a Small Computer System Interface (SCSI), or a combination thereof. The interface 834 may have a data processing speed that is faster than the operating speed of the non-volatile memory 831. Here, the buffer memory 832 may serve to temporarily store data. The data received from the interface 834 may be temporarily stored in the buffer memory 832 via the controller 833, and then semi-permanently stored in the non-volatile memory 831 at a data write speed of the non-volatile memory 831. Further, frequently-used items of the data stored in the non-volatile memory 831 may be temporarily stored in the buffer memory 832. That is, the buffer memory 832 may serve to increase an effective operating speed of the SSD 830, and reduce an error rate. The controller 833 may include a memory controller (not shown) and a buffer controller (not shown). The non-volatile memory 831 may be formed adjacent or close to the controller 833, and may be electrically connected thereto. A data storage capacity of the SSD 830 may correspond to a capacity of the non-volatile memory 831. The buffer memory 832 may be formed adjacent or close to the controller 833 and may be electrically connected thereto.

The non-volatile memory 831 may be connected to the interface 834 via the controller 833. The non-volatile memory 831 may serve to store data received through the interface 834. Even when the power supplied to the SSD 830 is interrupted, the data stored in the non-volatile memory 831 may be retained.

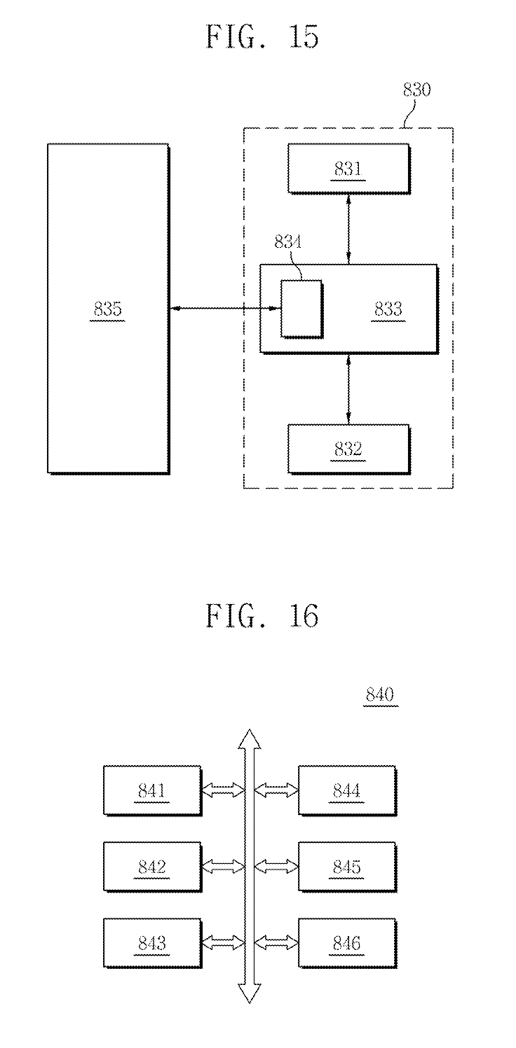

FIG. 16 is a block diagram schematically illustrating an electronic system including a semiconductor module according to an embodiment of the inventive concept.

Referring to FIG. 16, an electronic system 840 according to an exemplary embodiment of the inventive concept may include a control unit 841, an input unit 842, an output unit 843, and a storage unit 844, and further include a communication unit 845, and/or another operation unit 846.

The control unit 841 may control the electronic system 840, and the respective parts therein. The control unit 841 may be a central processor or a central controller, and may include an electronic circuit substrate 820 according to an exemplary embodiment of the inventive concept. The control unit 841 may include a semiconductor module 810, depicted in FIG. 13, that includes a semiconductor package according to an embodiment of the inventive concept. The input unit 842 may send an electrical command signal to the control unit 841. The input unit 842 may be a keyboard, a keypad, a mouse, a touch pad, an image recognizer such as a scanner, or any other input sensor. The input unit 842 may include a semiconductor module 810. The output unit 843 may receive an electrical command signal from the control unit 841, and output a result processed by the electronic system 840. The output unit 843 may be a monitor, a printer, a beam projector, or any other mechanical device. The output unit 843 may include a semiconductor module 810.

The storage unit 844 may temporarily or permanently store electrical data that has been or will be processed by the control unit 841. The storing unit 844 may be physically and electrically connected or coupled to the control unit 841. The storage unit 844 may be a semiconductor memory, a magnetic storage device such as a hard disk, an optical storage device such as a compact disk, or a server. The storage unit 844 may further include a semiconductor module 810. The communication unit 845 may send or receive an electrical command signal to or from the control unit 841, and then send or receive an electrical signal to or from another electronic system. The communication unit 845 may be a modem, a wired sending and receiving device such as a local area network (LAN) card, a wireless sending and receiving device such a WiBro wireless broadband interface, or an infrared (IR) port. The communication unit 845 may also include a semiconductor module 810. The operation unit 846 may be physically or mechanically operated according to a command from the control unit 841. For example, the operation unit 846 may be a plotter, an indicator, or an up/down operator. An electronic system according to an embodiment of the inventive concept may be a computer, a network server, a network printer or scanner, a wireless controller, a mobile communication terminal, an exchange, or any other programmable electronic product.

According to exemplary embodiments of the inventive concept, a dicing process may form a groove in a top surface of a semiconductor wafer and a reforming region in the semiconductor wafer. The reforming region may be formed using a laser transmitted through a bottom surface of the semiconductor wafer and focused in the semiconductor wafer.

After the dicing process, a grinding process and a chip separation process may be performed. Performing the dicing process before the grinding process, allows the semiconductor wafer to be treated during the dicing process and can improve manufacturing productivity.

The chip separation process may include separating the semiconductor wafer along the groove and the reforming region. Accordingly, due to the reforming region, even if a thin groove is formed, the semiconductor wafer may be separated.

Thus, contaminant materials and defects generated when the groove is formed may be minimized.

The foregoing is illustrative of the exemplary embodiments and is not to be construed as limiting thereof Although a few exemplary embodiments have been described, those skilled in the art will readily appreciate that many modifications are possible in exemplary embodiments without materially departing from the novel teachings and features. Accordingly, all such modifications are intended to be included within the scope of embodiments of the inventive concept as defined in the claims. Therefore, it is to be understood that the foregoing is illustrative of various exemplary embodiments and is not to be construed as limited to the specific embodiments disclosed, and that modifications to the disclosed embodiments, as well as other embodiments, are intended to be included within the scope of the appended claims.

1. A method of fabricating a semiconductor device, comprising:
loading a semiconductor wafer having a top surface and a bottom surface onto a wafer chuck, wherein the bottom surface of the loaded semiconductor wafer faces the wafer chuck;
forming a groove in the top surface of the loaded semiconductor wafer by irradiating a second laser onto the top surface of the semiconductor wafer;
forming a reforming region within the loaded semiconductor wafer under the groove in the semiconductor wafer by focusing a first laser in the semiconductor wafer, wherein light from the first laser transmits through the wafer chuck and the bottom surface of the semiconductor wafer to the focused regions in the semiconductor wafer to reform the inside of the semiconductor wafer;
unloading the semiconductor wafer from the wafer chuck.

2. The method of claim 1, wherein the wafer chuck is formed of a material transparent to visible and infrared light.

3. The method of claim 1, wherein the groove is wider than the reforming region.

4. The method of claim 1, further comprising grinding the bottom surface of the unloaded semiconductor wafer to decrease a thickness of the semiconductor wafer, forming a thinner semiconductor wafer, wherein the reforming region is unaffected by the decrease in semiconductor wafer thickness.

5. The method of claim 1, wherein the groove and the reforming region are simultaneously formed.

6. The method of claim 1, wherein the second laser emits a light different from that of the first laser.

7. The method of claim 6, wherein the first laser is an infrared laser, and the second laser is an ultraviolet laser.

8. The method of claim 4, further comprising separating the semiconductor wafer along the groove and the reforming region to form a plurality of unit chips.

9. The method of claim 8, wherein separating the semiconductor wafer comprises:
adhering the thinner semiconductor wafer to an extension tape; and
stretching the extension tape to separate the semiconductor wafer along the groove and the reforming region.

10. A method of fabricating a semiconductor device, comprising:
loading a semiconductor wafer having a top surface and a bottom surface onto a top surface of a wafer chuck;
forming a groove in the top surface of the loaded semiconductor wafer, and forming a reforming region in the loaded semiconductor wafer, the reforming region being formed under the groove in the semiconductor wafer;
unloading the semiconductor wafer from the wafer chuck;
grinding the bottom surface of the unloaded semiconductor wafer to decrease a thickness of the semiconductor wafer, forming a thinner semiconductor wafer;
adhering an extension tape to the ground bottom surface of the semiconductor wafer;
stretching the extension tape to separate the semiconductor wafer along the groove and the reforming region to form a plurality of unit chips; and
packaging the unit chips.

11. The method of claim 10, wherein the semiconductor wafer includes a semiconductor substrate region, an integrated circuit forming region on the semiconductor substrate region, an interconnection and pad forming region on the integrated circuit forming region, the interconnection and pad forming region being provided on the top surface of the semiconductor wafer,
the semiconductor wafer includes chip regions and cut regions between the chip regions,
the groove is formed in the cut region and extends into the semiconductor substrate region through the interconnection and pad forming region and the integrated circuit forming region, and
the reforming region is formed in the cut region under the groove in the semiconductor substrate region.

12. The method of claim 10, wherein the reforming region is formed under the groove in the semiconductor wafer and is spaced apart from the groove.

13. The method of claim 10, wherein the reforming region is spaced apart from the bottom surface of the thinner semiconductor wafer.

14. The method of claim 10, wherein the reforming region includes one or more separated reforming regions.

15. The method of claim 10, wherein the reforming region includes one or more partially overlapping reforming regions.

16. The method of claim 10, wherein a part of the wafer chuck on which the semiconductor wafer is disposed is formed of a transparent material.

17-19. (canceled)
